(19) United States
(12) Patent Application Publication
(10) Pub. No.: US 2026/0342340 A1
(43) Pub. Date: Oct. 29, 2026

(54) APPARATUS, SYSTEM, AND METHOD FOR ENERGY AND POWER-QUALITY AWARE COMPUTE, ANALYSIS, AND CONTROL

(71) Applicant: Renewable Edge LLC, Honolulu, HI (US)

(72) Inventors: Kevin Lee Davies, Honolulu, HI (US); Mohamad Mehdi Nasr-Azadani, San Mateo, CA (US); Anthony Michael Reffle, Houston, TX (US)

(21) Appl. No.: 19/556,943

(22) Filed: Mar. 4, 2026

Related U.S. Application Data
(60) Provisional application No. 63/766,665, filed on Mar. 4, 2025.

(51) Int. Cl. H03L 7/08; G05B 13/02

(52) U.S. Cl. CPC H03L 7/08; G05B 13/0265

(57) ABSTRACT

A system for energy and PQ-aware compute, analysis, and control may include a sensor and circuitry. The sensor may be configured to output power waveform data representative of measurements from an electrical power system. The circuitry may be configured to execute, in a privileged space, a component that extracts at least one PQ indicator of the electrical power system from the power waveform data and that enforces, based at least in part on the PQ indicator, a policy in connection with the electrical power system by performing at least one action in connection with the electrical power system or the circuitry. Various other apparatuses, systems, methods, and computer-readable media are also disclosed.

### CROSS REFERENCE TO RELATED APPLICATION

This application claims the benefit of U.S. Provisional Application No. 63/766,665 filed Mar. 04, 2025, the disclosure of which is incorporated in its entirety by this reference.

### BACKGROUND

Some electric power systems that supply critical loads, including modern data centers and industrial facilities, are increasingly subjected to power-quality (PQ) disturbances and/or operational constraints that arise from high power-density loads, time-varying price signals, and/or the growing use of converter-based resources like photovoltaic generation and/or battery systems. These conditions may impact service continuity, equipment performance, and/or the ability of operators to meet certain business and/or reliability objectives while complying with certain utility and/or infrastructure requirements.

Some conventional PQ monitoring approaches may rely on event-triggered or windowed capture methods that record waveform data only around detected threshold crossings or in periodic limited-duration windows. Such methods may create observation gaps that miss transient conditions that would otherwise help explain equipment behavior, failures, and/or compliance issues. Moreover, because such conventional approaches commit to a single analysis representation at capture time, they preclude retroactive analysis using methods or time scales not anticipated when the data was recorded. In addition, some conventional system architectures may depend on rigid and/or domain-specific mappings to translate high-level policies or objectives into low-level sensing, computation, and/or control operations. Unfortunately, such operations may be difficult to maintain in distributed real-time environments where operational context, environmental conditions, and analytical objectives may change over time, and where bandwidth, latency, and/or security constraints may further limit the ability to reconfigure sensing, computation, and/or control behavior at runtime.

The instant disclosure, therefore, identifies and addresses a need for improved apparatuses, systems, and methods for energy and PQ-aware compute, analysis, and control.

### SUMMARY

As will be described in greater detail below, the instant disclosure generally relates to apparatuses, systems, and methods for energy and PQ-aware compute, analysis, and control. In some examples, a system includes a sensor and circuitry. In one example, the sensor is configured to output power waveform data representative of measurements from an electrical power system. In this example, the circuitry is configured to execute, in a privileged space, a component that extracts at least one PQ indicator of the electrical power system from the power waveform data and that enforces, based at least in part on the PQ indicator, a policy in connection with the electrical power system by performing at least one action in connection with the electrical power system or the circuitry.

In some examples, the circuitry comprises a hardware-based processor configured to implement an operating system (OS) kernel that executes the component. In one example, the component comprises an extended Berkeley Packet Filter (eBPF) program. Additionally or alternatively, the component is attached to an eXpress Data Path (XDP) hook point or Traffic Control (TC) hook point such that the circuitry associates an XDP or TC mechanism to a network interface and automatically invokes the XDP or TC mechanism in response to the power waveform data arriving at the network interface.

In some examples, the sensor is further configured to output additional power waveform data representative of additional measurements from the electrical power system, and the component further routes the additional power waveform data to user space via an Address Family eXpress Data Path (AFXDP) socket path. In one example, the user space further receives the additional power waveform data via direct streaming and feeds the additional waveform data to a target for processing or storage in connection with the policy.

In some examples, the component further routes the PQ indicator to user space via at least one shared data structure. In one example, the user space further receives the PQ indicator via the shared data structure and feeds the PQ indicator to an application that analyzes a power quality of the electrical power system based at least in part on the PQ indicator.

In some examples, the user space further receives the PQ indicator from the component in response to detection of a PQ violation and feeds the PQ indicator to an application that analyzes a power quality of the electrical power system based at least in part on the PQ indicator. In one example, the system further comprises an interrupt configured to signal arrival of the power waveform data, and the component is further configured to analyze the power waveform data for the PQ violation in response to an event triggered by the interrupt and to detect the PQ violation based at least in part on the analysis of the power waveform data.

In some examples, the component further implements a feedback loop for dynamically adaptive sampling of the power waveform data to balance resolution versus resource usage. In one example, the component further changes the operating state of at least one compute resource by at least one of executing an Advanced Configuration and Power Interface (ACPI) method call to adjust a power state of a hardware-based processor included in the circuitry or configuring a frequency scaling setting of a hardware-based processor included in the circuitry.

In some examples, the action comprises at least one of changing an operating state of at least one compute resource of the circuitry or changing an operating state of at least one energy resource of the electrical power system. In some examples, the circuitry is further configured to implement an artificial intelligence (AI) model that analyzes a state of the electrical power system based at least in part on the PQ indicator or performs decision-making in connection with the enforcement of the policy based at least in part on the PQ indicator.

In some examples, the circuitry is further configured to implement an artificial intelligence (AI) model that directs the component in the privileged space to extract the PQ indicator from the power waveform data or enforce the policy in connection with the electrical power system. In one example, the privileged space comprises at least one of kernel space, a virtual machine environment, or microcontroller firmware. Additionally or alternatively, the system further comprises an interface configured to communicatively couple the sensor to the circuitry and transfers the power waveform data from the sensor to the circuitry over a network using Transmission Control Protocol/Internet Protocol (TCP/IP).

In some examples, a corresponding apparatus includes a sensor node and a gateway. In one example, the sensor node includes one or more sensors configured to output power waveform data representative of measurements from an electrical power system. In this example, the gateway is configured to execute, in a privileged space, a component that extracts at least one PQ indicator of the electrical power system from the power waveform data and that enforces, based at least in part on the PQ indicator, a policy in connection with the electrical power system by performing at least one action in connection with the electrical power system, the sensor node, or the gateway. In certain embodiments, the gateway is further configured to implement an operating system (OS) kernel that executes the component.

In some examples, a corresponding method includes (1) outputting, by a sensor included in the computing system, power waveform data representative of measurements from an electrical power system and (2) executing, by circuitry included in the computing system, a privileged-space component that (A) extracts at least one PQ indicator of the electrical power system from the power waveform data and (B) enforces, based at least in part on the PQ indicator, a policy in connection with the electrical power system by performing at least one action in connection with the electrical power system or the circuitry.

Features from any of the above-mentioned embodiments may be used in combination with one another in accordance with the general principles described herein. These and other embodiments, features, and advantages will be more fully understood upon reading the following detailed description in conjunction with the accompanying drawings and claims.

### BRIEF DESCRIPTION OF THE DRAWINGS

The accompanying drawings illustrate a number of exemplary embodiments and are a part of the specification. Together with the following description, these drawings demonstrate and explain various principles of the instant disclosure.

FIG. 1 is an illustration of an exemplary system for energy and PQ-aware compute, analysis, and control in accordance with one or more embodiments of this disclosure.

FIG. 2 is an illustration of an exemplary system for energy and PQ-aware compute, analysis, and control in accordance with one or more embodiments of this disclosure.

FIG. 3 is an illustration of an exemplary implementation of a system for energy and PQ-aware compute, analysis, and control in accordance with one or more embodiments of this disclosure.

FIG. 4 is an illustration of an exemplary physical measurement stage of a system for energy and PQ-aware compute, analysis, and control in accordance with one or more embodiments of this disclosure.

FIG. 5 is an illustration of an exemplary privileged-space pre-processing stage of a system for energy and PQ-aware compute, analysis, and control in accordance with one or more embodiments of this disclosure.

FIG. 6 is an illustration of an exemplary user-space multi-modal processing stage of a system for energy and PQ-aware compute, analysis, and control in accordance with one or more embodiments of this disclosure.

FIG. 7 is an illustration of an exemplary semantic enrichment, artificial intelligence (AI), and control stage of a system for energy and PQ-aware compute, analysis, and control in accordance with one or more embodiments of this disclosure.

FIG. 8 is an illustration of an exemplary output surfaces stage of a system for energy and PQ-aware compute, analysis, and control in accordance with one or more embodiments of this disclosure.

FIG. 9 is an illustration of an exemplary persistence stage of a system for energy and PQ-aware compute, analysis, and control in accordance with one or more embodiments of this disclosure.

FIG. 10 is a flow diagram of an exemplary method for energy and PQ-aware compute, analysis, and control in accordance with one or more embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the instant disclosure covers all modifications, equivalents, and alternatives falling within the scope of the appended claims.

### DETAILED DESCRIPTION OF EXEMPLARY EMBODIMENTS

The present disclosure describes various apparatuses, systems, and methods for energy and PQ-aware compute, analysis, and control. In some examples, the disclosed technology provides an end-to-end architecture for continuously monitoring an electrical power system using high-fidelity power waveform measurements. The disclosed technology may do so by extracting one or more PQ indicators with low latency and enforcing one or more policies based on the extracted indicators. In one example, the end-to-end architecture is structured to reduce the observation gaps and/or delayed responses that may occur in conventional windowed and/or event-capture monitoring approaches. In this example, the end-to-end architecture facilitates avoiding the overhead and/or non-determinism associated with relying exclusively on user-space processing for high-rate waveform streams.

In some examples, one or more sensors (e.g., a sensor node having multiple sensors) acquire voltage and/or current measurements and then output power waveform data representative of the state of the electrical power system. In one example, the power waveform data may be transferred to a computing platform (e.g., a gateway and/or server) over a network interface. In this example, the computing platform may execute and/or implement a component positioned close to data ingress in the data processing pipeline. For example, the component may reside, run, and/or be maintained in a privileged space (e.g., kernel space, a virtual machine environment, firmware, and/or any other space or container external to and/or outside user space). In this example, the computing platform may compute and/or act upon PQ indicators derived from the power waveform data without waiting for higher-latency application-layer pipelines.

In some examples, the privileged-space component may be executed and/or implemented as an extended Berkeley Packet Filter (eBPF) program attached to an eXpress Data Path (XDP) hook point and/or a Traffic Control (TC) hook point such that the eBPF logic is automatically invoked as waveform packets arrive at the network interface. In one example, the placement and/or invocation of the eBPF logic facilitates and/or supports early extraction of PQ indicators from the waveform stream and/or making policy enforcement decisions in a deterministic execution context.

In some examples, the computing platform may export information from privileged space to user space along multiple paths—depending on the intended downstream use of the information. In one example, the privileged-space component may route additional waveform data to user space via an Address Family eXpress Data Path (AFXDP) socket path for direct streaming to a target used for processing and/or storage. In this example, the privileged-space component may route PQ indicators to user space via a shared data structure for consumption by an application that analyzes the power quality of the electrical power system. In certain implementations, the privileged-space component may deliver the PQ indicators to user space in response to detecting a PQ violation. As a result, user-space applications may be able to focus computation and/or reporting on relevant intervals or events.

In some examples, the computing platform may use event-driven triggering to further reduce latency and/or wasted computation. For example, the computing platform may include and/or represent interrupts configured to signal arrival of power waveform data so that the privileged-space component analyzes the power waveform data for PQ violations in response to such signals. This event-driven triggering may serve and/or function as an alternative to polling-oriented workflows that impose avoidable latency and/or processing overhead in high-rate PQ monitoring.

In some examples, the computing platform may enforce energy-related and/or power-related policies as one or more actions that affect—whether directly or indirectly—the electrical power system, the sensors, and/or the computing platform. In one example, the privileged-space component participates in a feedback loop for dynamically adaptive sampling of the waveform data to balance measurement resolution against resource usage. For example, the privileged-space component may cause and/or lead to reconfiguring the acquisition behavior of the sensors that take the power measurements of the electrical power system.

In some examples, policy-enforcement actions may involve changing the operating state of compute resources included in the sensors and/or the computing platform. For example, a policy-enforcement action may involve executing an Advanced Configuration and Power Interface (ACPI) method call to adjust the power state of a processor and/or configuring a frequency scaling setting of a processor. Additionally or alternatively, a policy-enforcement action may involve changing the operating state of one or more energy resources in the electrical power system (e.g., controllable generation or storage resources) in response to certain detectable PQ conditions.

In some examples, the computing platform may execute and/or implement an artificial intelligence (AI) model to analyze the state of the electrical power system based at least in part on the extracted power-quality (PQ) indicators. In one example, the AI model may perform decision-making in connection with policy enforcement. Additionally or alternatively, the AI model may direct the privileged-space component in connection with indicator extraction and/or policy enforcement while retaining the privileged-space component for low-latency operation on incoming waveform data.

In some examples, the disclosed technology addresses certain shortcomings and/or deficiencies found in conventional PQ monitoring approaches, including (1) missed transient events and diagnostic gaps associated with spot-check or short-window capture behavior, (2) rigidity of subsystems that are unable to adapt sensing and/or analysis behavior at runtime, and/or (3) latency and packet-loss risks that arise when high-bandwidth waveform streams are processed only after traversing conventional user-space stacks and/or interfaces. Accordingly, the privileged-space processing—coupled with selective routing of waveform data and/or compact PQ indicators to user space for closed-loop policy enforcement—may support continuous monitoring while maintaining manageable resource usage and/or performing timely actions.

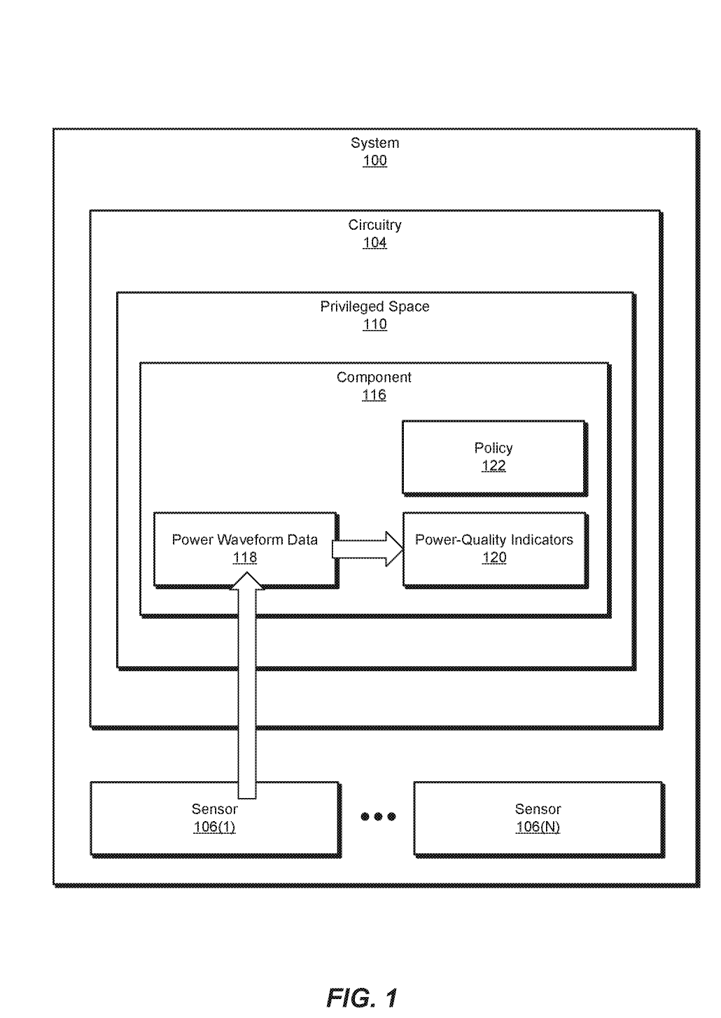

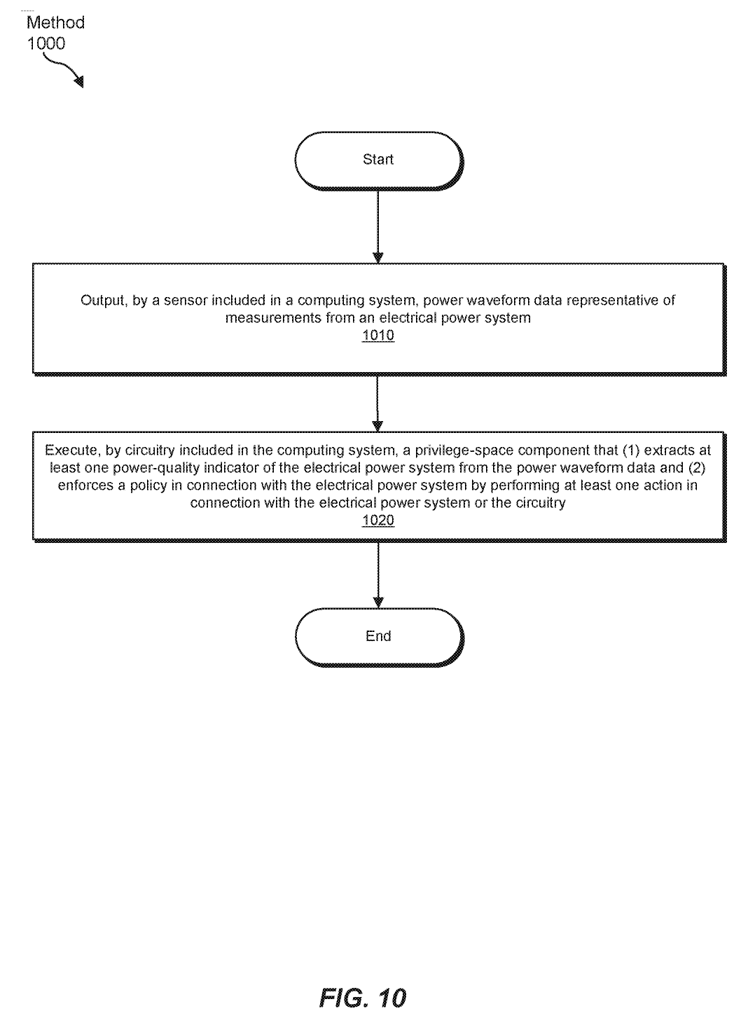

The following will provide, with reference to FIGS. 1-9, detailed descriptions of exemplary devices, systems, and corresponding implementations for energy and PQ-aware compute, analysis, and control. Detailed descriptions of an exemplary method for energy and PQ-aware compute, analysis, and control will be provided in connection with FIG. 10.

FIG. 1 illustrates an exemplary system 100 for energy and PQ-aware compute, analysis, and control. As illustrated in FIG. 1, system 100 may include circuitry 104 and one or more sensors 106(1)-(N). In some examples, circuitry 104 and sensors 106(1)-(N) may be communicatively and/or electrically coupled to one another. In one example, sensors 106(1)-(N) may output power waveform data 118 representative of measurements (e.g., voltage, current, power, etc.) from an electrical power system. In this example, circuitry 104 may execute and/or implement a component 116 in privileged space 110.

In some examples, privileged space 110 may include and/or represent an execution environment that operates outside of user space and/or provides elevated access and/or earlier processing relative to user-space execution. In one example, privileged space 110 may include and/or represent kernel space, a virtual machine environment, and/or system firmware (e.g., microcontroller firmware). In certain implementations, privileged space 110 may include and/or represent an execution environment that provides deterministic scheduling sufficient to keep pace with the power waveform data, isolation such that external processes are unable to alter data within the execution environment, and resource containment such that components within the execution environment are unable to disrupt platform stability.

By running in privileged space 110 rather than user space, component 116 may process power waveform data 118 closer to data ingress (e.g., at a network interface via an XDP or TC hook point) and/or extract one or more PQ indicators 120 from power waveform data 118 for consideration in enforcing one or more policies. Examples of privileged space 110 include, without limitation, kernel space, a virtual machine environment, firmware (e.g., microcontroller firmware), combinations or variations of one or more of the same, and/or any other suitable privileged space.

In contrast to privileged space 110, user space may include and/or represent an application-level execution context that receives outputs produced by component 116 and/or passed through privileged space 110. In one example, applications and services may run in user space, and an operating system (OS) kernel may run in privileged and/or kernel space. In this example, user space may receive and/or obtain power waveform data via an AFXDP socket path and/or PQ indicators 120 via one or more shared data structures (e.g., BPF maps and ring buffers). Additionally or alternatively, user space may feed such power waveform data to a target (e.g., a user-space application, a shared memory buffer, analytics engine, etc.) for further processing, storage, and/or analysis.

In some examples, component 116 in privileged space 110 may extract one or more PQ indicators 120 from power waveform data 118 for consideration in enforcing one or more policies. In one example, component 116 may apply and/or enforce a policy 122 in connection with the electrical power system based at least in part on PQ indicators 120. In this example, to do so, component 116 may perform one or more actions in connection with the electrical power system, sensors 106(1)-(N), and/or circuitry 104 before or while routing data and/or results onward for user-space handling. For example, component 116 may dynamically change and/or alter the operating state of one or more compute resources of circuitry 104. In another example, component 116 may dynamically change and/or alter the operating state of one or more sampling resources of sensors 106(1)-(N). Additionally or alternatively, component 116 may dynamically change and/or alter the operating state of one or more energy resources of the electrical power system.

In some examples, policy 122 may include and/or represent one or more rules, thresholds, objectives, and/or decision logic that governs how component 116 and/or circuitry 104 responds to PQ indicators 120. In one example, policy 122 may specify when system 100 treats a condition as a PQ violation, how system 100 prioritizes competing objectives (e.g., power quality, compute performance, energy consumption, etc.), and which actions system 100 takes in response. In certain implementations, policy 122 may include and/or represent an energy-management policy that indicates the action for changing the operating state of the compute resource, the energy resource, and/or the sampling resource. For example, policy 122 may direct component 116 to reduce, increase, pause, and/or otherwise adjust compute activity and/or to initiate a control action that affects an energy resource based at least in part on a detected or predicted PQ condition.

In some examples, policy 122 may include and/or represent decision logic implemented and/or assisted by an AI model. In one example, the AI model may analyze the state of the electrical power system based at least in part on PQ indicators 120 and/or performs decision-making for enforcement of policy 122 based at least in part on PQ indicators 120. Additionally or alternatively, policy 122 may identify which data and/or results system 100 is to route onward for downstream handling (e.g., routing selected waveform data and/or extracted PQ indicators for processing or storage) in connection with enforcement of policy 122.

In some examples, circuitry 104 may implement an operating system (OS) kernel that executes component 116. In one example, component 116 may include and/or represent an extended Berkeley Packet Filter (eBPF) program. Additionally or alternatively, system 100 may include and/or represent a network interface that receives power waveform data 118 (e.g., in the form of packets). In certain implementations, component 116 may attach to an XDP hook point or a TC hook point, and circuitry 104 may associate an XDP or TC mechanism with the network interface. In such implementations, the XDP or TC mechanism may automatically invoke component 116 in response to power waveform data 118 arriving at the network interface.

In some examples, sensors 106(1)-(N) may output additional power waveform data representative of additional power measurements, and component 116 may route the additional power waveform data to user space via an AFXDP socket path. In one example, user space may receive the additional power waveform data via direct streaming. In this example, user space may feed the additional power waveform data to a target (e.g., a specific application) for processing or storage in connection with the policy 122. Additionally or alternatively, component 116 may route the PQ indicators 120 to user space via one or more shared data structures. In one example, user space may receive PQ indicators 120 via the shared data structure(s) and/or feed the PQ indicators 120 to an application that analyzes the power quality of the electrical power system based at least in part on PQ indicators 120.

In some examples, component 116 may detect a PQ violation, and in response, user space may receive PQ indicators 120 from component 116. In such examples, user space may feed PQ indicators 120 to the application that then analyzes the power quality of the electrical power system based at least in part on PQ indicators 120. In one example, system 100 may include and/or apply an interrupt that signals arrival of power waveform data 118, and component 116 may analyze the power waveform data 118 for the PQ violation in response to an event triggered by the interrupt. In this example, component 116 may detect the PQ violation based at least in part on the analysis of power waveform data 118.

In some examples, component 116 may implement a feedback loop for dynamically adaptive sampling of power waveform data 118 to balance and/or tune resolution versus resource usage. In one example, component 116 may change the operating state of a compute resource by executing an ACPI method call to adjust the power state of a hardware-based processor included in circuitry 104 and/or by setting a frequency scaling setting of the hardware-based processor.

In some examples, circuitry 104 may implement an AI model that analyzes the state of the electrical power system based at least in part on PQ indicators 120. In one example, the AI model may perform decision-making in connection with enforcement of policy 122 based at least in part on PQ indicators 120. Additionally or alternatively, the AI model may direct component 116 in privileged space 110 to extract PQ indicators 120 from the power waveform data 118 and/or enforce policy 122 in connection with the electrical power system.

In some examples, system 100 may include and/or represent one or more interfaces that communicatively couple sensors 106(1)-(N) to circuitry 104. In one example, such interfaces may transfer power waveform data 118 from sensors 106(1)-(N) to circuitry 104 over a network using Transmission Control Protocol/Internet Protocol (TCP/IP).

In some examples, circuitry 104 may include and/or represent one or more electrical and/or electronic circuits capable of processing, applying, modifying, transforming, displaying, transmitting, receiving, and/or executing data for system 100. Additionally or alternatively, circuitry 104 may launch, perform, and/or execute certain executable files, code snippets, and/or computer-readable instructions for energy and PQ-aware compute, analysis, and control. In one example, circuitry 104 may be distributed across multiple physical devices included in system 100 and/or in a network. For example, circuitry 104 may be distributed across a sensor node and a gateway (e.g., a server).

Although illustrated as a single unit in FIG. 1, circuitry 104 may include and/or represent a collection of multiple processing units and/or electrical or electronic components that work and/or operate in conjunction with one another. Examples of circuitry 104 include, without limitation, application-specific integrated circuits (ASICs), central processing units (CPUs), graphics processing units (GPUs), microprocessors, microcontrollers, field-programmable gate arrays (FPGAs), systems on chips (SoCs), storage devices, memory devices, caches, logical circuitry, analog circuitry, portions of one or more of the same, variations or combinations of one or more of the same, and/or any other suitable circuitry. In some examples, system 100 may include and/or represent various physical computing devices capable of reading computer-executable instructions and/or providing PQ-aware compute, analysis, and control.

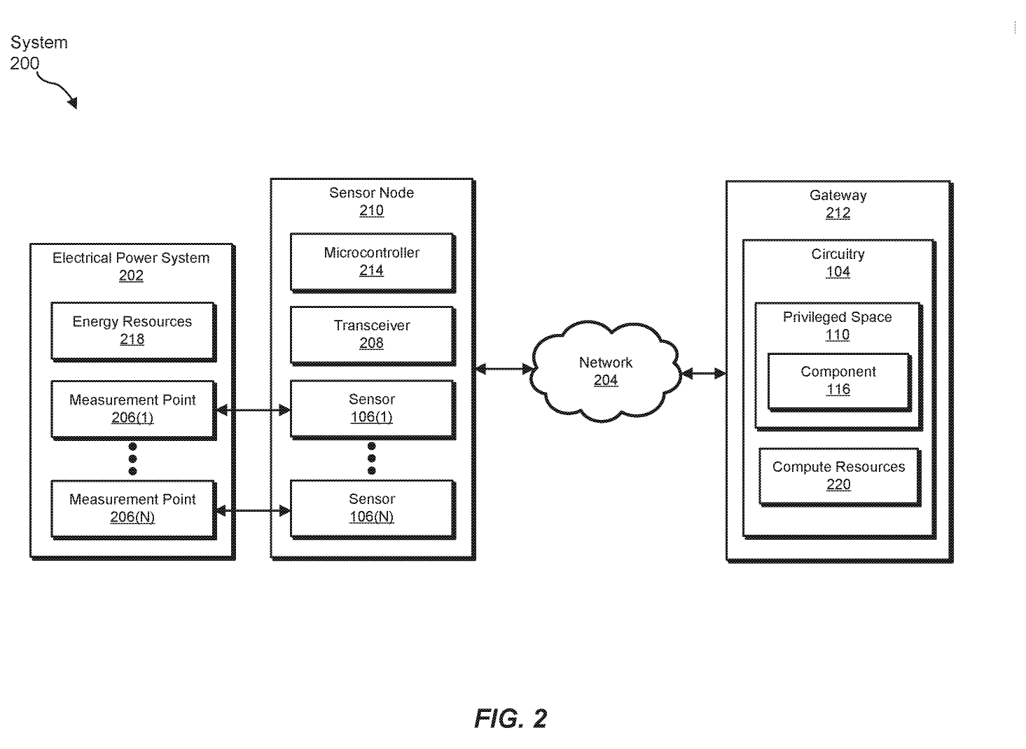

FIG. 2 illustrates an exemplary system 200 that facilitates and/or supports PQ-aware measurement, communication, and control in connection with an electrical power system. In some examples, system 200 may include and/or involve certain devices, components, configurations, and/or features that perform and/or provide functionalities that are similar and/or identical to those described above in connection with FIG. 1. As illustrated in FIG. 2, system 200 may include and/or represent an electrical power system 202, a sensor node 210, and/or a gateway 212. In one example, sensor node 210 may be electrically coupled to electrical power system 202 at one or more measurement points 206(1)-(N). Additionally or alternatively, sensor node 210 may be communicatively coupled to gateway 212 via network 204.

In some examples, sensor node 210 may include and/or represent sensors 106(1)-(N) that interface with electrical power system 202 via measurement points 206(1)-(N). Additionally or alternatively, electrical power system 202 may include and/or provide measurement points 206(1)-(N). In such examples, sensor node 210 may take and/or obtain measurement data from measurement points 206(1)-(N) and then prepare the measurement data for transport as a power waveform stream. In one example, sensor node 210 may include and/or represent a transceiver 208 that communicates and/or transmits the power waveform stream over network 204 to gateway 212.

In some examples, sensor node 210 may include and/or represent a microcontroller 214 that performs local sensing, timing, buffering, and/or packaging of power waveform stream prior to transmission via transceiver 208. Additionally or alternatively, microcontroller 214 may perform local screening and/or tagging of power waveform stream for purposes of prioritizing, reducing, or otherwise conditioning certain measurement data.

In some examples, gateway 212 may include and/or implement component 116 used to ingest the power waveform stream and/or to determine one or more PQ conditions based at least in part on the power waveform stream. In such examples, gateway 212 may implement and/or execute one or more workflows that support monitoring, analytics, and/or decision-making in connection with electrical power system 202. In one example, gateway 212 may include and/or represent circuitry 104 that implements and/or comprises compute resources 220.

In some examples, electrical power system 202 may include and/or represent one or more energy resources 218. In such examples, gateway 212 may coordinate the operation of energy resources 218 based at least in part on the determined PQ conditions. Additionally or alternatively, gateway 212 may cause at least one control action to be taken in connection with electrical power system 202. Such control actions may involve dynamically altering and/or affecting energy resources 218 and/or how measurement data is collected and/or transmitted by sensor node 210.

In some examples, network 204 may include one or more wired and/or wireless network segments, and transceiver 208 may support one or more communication modes for transporting the power waveform stream from sensor node 210 to gateway 212. In certain implementations, system 200 may scale by including multiple instances of sensor node 210 distributed across measurement points 206(1)-(N) of electrical power system 202 and communicating measurement data to gateway 212 via network 204.

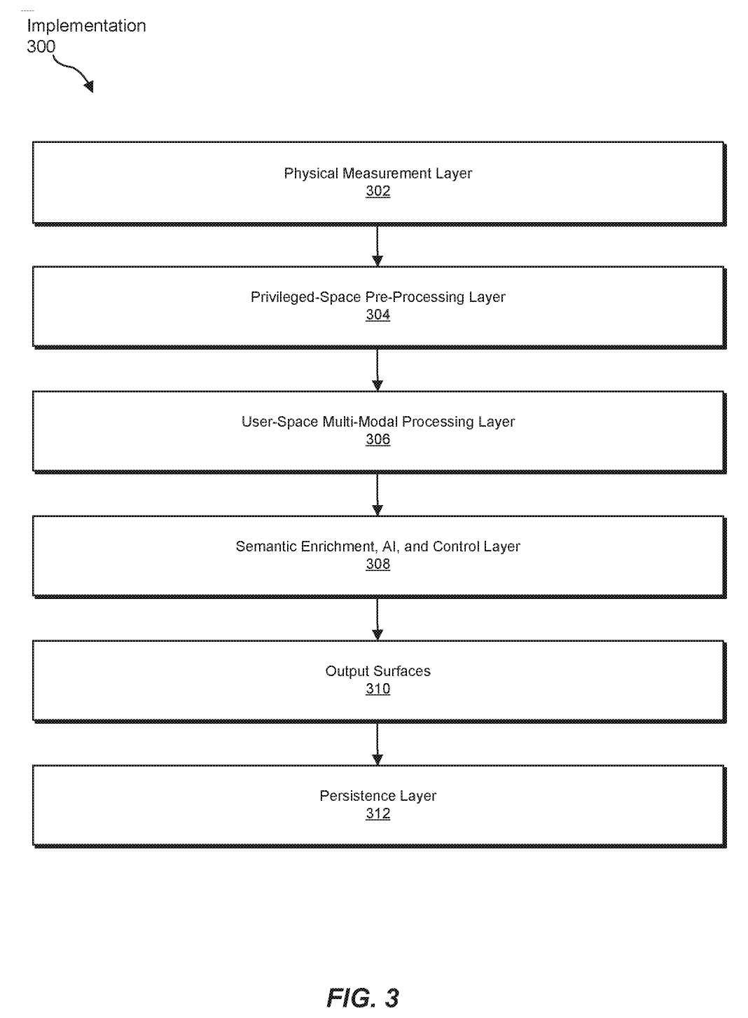

FIG. 3 illustrates an exemplary implementation 300 of a system for continuous waveform processing using a multi-tier, multi-modal, and/or multi-scale architecture. In some examples, implementation 300 may include and/or involve certain devices, components, configurations, and/or features that perform and/or provide functionalities that are similar and/or identical to those described above in connection with any of FIGS. 1-2. As illustrated in FIG. 3, implementation 300 may include and/or represent a physical measurement layer 302, a privileged-space pre-processing layer 304, a user-space multi-modal processing layer 306, a semantic enrichment, AI, and control (SEAC) layer 308, one or more output surfaces 310, and/or a persistence layer 312. In one example, the various layers and/or features illustrated in FIGS. 3-9 may be distributed across and/or implemented by multiple physical devices (e.g., electrical power system 202, sensor node 210, gateway 212, etc.).

In some examples, physical measurement layer 302 may receive analog electrical conditions from electrical power system 202 at one or more measurement points 206(1)-(N). In one example, physical measurement layer 302 may process the electrical conditions to generate digitized waveform samples representative of those conditions. In this example, physical measurement layer 302 may output a continuous waveform data stream (e.g., voltage and/or current sample streams) along with associated timing information and/or metadata that indicates when and/or where the samples were captured.

In some examples, privileged-space pre-processing layer 304 may ingest the continuous waveform data stream output by physical measurement layer 302. In such examples, privileged-space pre-processing layer 304 may process the continuous waveform data stream to generate one or more privileged-space outputs that preserve waveform fidelity while preparing the data for downstream use. Such outputs may include and/or represent packaged waveform segments, compressed and/or rate-shaped waveform streams, event flags or triggers, and/or basic derived indicators suitable for low-latency routing and/or handling.

In some examples, user-space multi-modal processing layer 306 may ingest one or more of the packaged waveform segments, waveform streams, event flags, and/or derived indicators output by privileged-space pre-processing layer 304. In such examples, user-space multi-modal processing layer 306 may process the ingested data and then generate outputs that include structured measurements, features, and/or events computed from the waveform data as well as one or more waveform-derived representations suitable for downstream analytics, correlation, and/or interpretation.

In some examples, SEAC layer 308 may ingest the structured measurements, features, events, and/or representations output by user-space multi-modal processing layer 306. In such examples, SEAC layer 308 may process the ingested data and then generate and output enriched results that add interpretive context (e.g., inferred conditions, classifications, correlations, explanations, and/or recommended actions). In one example, SEAC layer 308 may also generate and output control intents, control decisions, and/or policy-relevant determinations derived from the ingested data.

In some examples, output surfaces 310 may ingest enriched results and/or control decisions and determinations output by user-space multi-modal processing layer 306 and/or SEAC layer 308. In such examples, output surfaces 310 may process the ingested data and then output operator-facing and/or system-facing deliverables like visualizations, reports, alerts, notifications, responses to queries, and/or machine-consumable outputs for integrations and downstream automation.

In some examples, persistence layer 312 may ingest one or more of the waveform data streams, packaged waveform segments, derived indicators, structured measurements, features, events, representations, enriched results, and/or control-related artifacts output by any of the other layers illustrated in FIG. 3. In such examples, persistence layer 312 may process the ingested data and then output stored data for later retrieval and use, including supporting replay, audit, historical analysis, compliance evidence generation, model training and/or evaluation, and query-driven access to both raw and derived information.

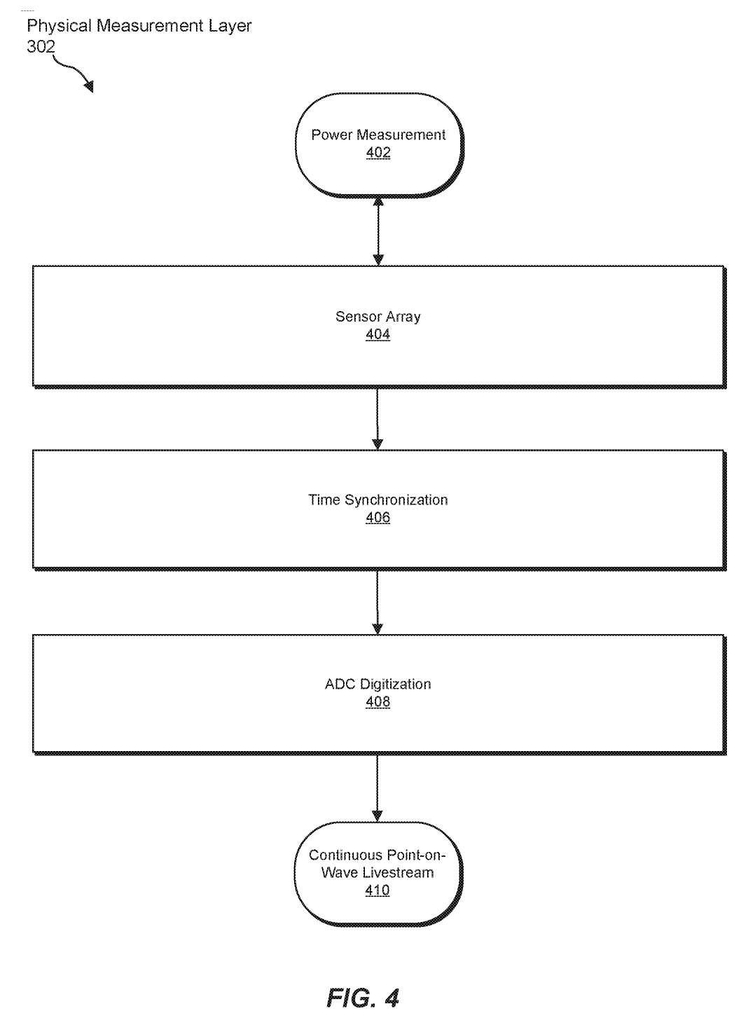

FIG. 4 illustrates an exemplary implementation of physical measurement layer 302 that facilitates and/or supports continuous point-on-wave acquisition for an electrical power system. In some examples, physical measurement layer 302 in FIG. 4 may include and/or involve certain devices, components, configurations, and/or features that perform and/or provide functionalities that are similar and/or identical to those described above in connection with any of FIGS. 1-3. As illustrated in FIG. 4, physical measurement layer 302 may include and/or involve a power measurement 402, a sensor array 404, a time synchronization 406, an analog-to-digital conversion (ADC) digitization 408, and a continuous point-on-wave (CPOW) livestream 410.

In some examples, power measurement 402 may include and/or represent acquisition of electrical conditions (e.g., voltage and/or current levels) at one or more measurement locations. In such examples, sensor array 404 may include and/or represent a set of sensing elements and/or interfaces coupled to the measurement locations. In one example, sensor array 404 may generate and/or produce one or more analog measurement signals and/or data corresponding to the electrical conditions. In this example, sensor array 404 may support multiple channels, such as voltage channels, current channels, power channels, and/or neutral channels. In certain implementations, sensor array 404 may include and/or implement galvanic separation at the measurement locations. For example, sensor array 404 may use fiber-optic isolation (e.g., plastic optical fiber and/or a 100 Base-FX transport) to provide galvanic separation while communicating measurement signals and/or measurement data from the measurement location to downstream equipment.

In some examples, time synchronization 406 may provide timing alignment for samples produced by ADC digitization 408. In one example, time synchronization 406 may include and/or represent time synchronization via a global positioning system (GPS) and/or Precision Time Protocol (PTP) such that digitized samples can be timestamped and/or otherwise associated with a common time reference across devices and/or measurement locations.

In some examples, ADC digitization 408 may involve digitizing the analog measurement signals produced by sensor array 404 at a certain sampling rate (e.g., approximately 32 kHz) and at a certain resolution (e.g., approximately 24 bits) across all channels simultaneously. In one example, ADC digitization 408 may involve digitizing multiple channels (e.g., three voltage channels, three current channels, and one neutral channel). In this example, ADC digitization 408 may produce digitized waveform samples that preserve waveform fidelity and/or enable downstream analysis at multiple time scales without requiring triggered capture and/or predetermined windowing at the time of acquisition.

In some examples, CPOW livestream 410 may include and/or represent an uninterrupted raw waveform data stream generated from the digitized waveform samples output by ADC digitization 408. In such examples, CPOW livestream 410 may capture substantially every sample of substantially every cycle with no observation gaps. As a result, CPOW livestream 410 may preserve a complete waveform record that supports retroactive and/or arbitrary-window analysis after acquisition.

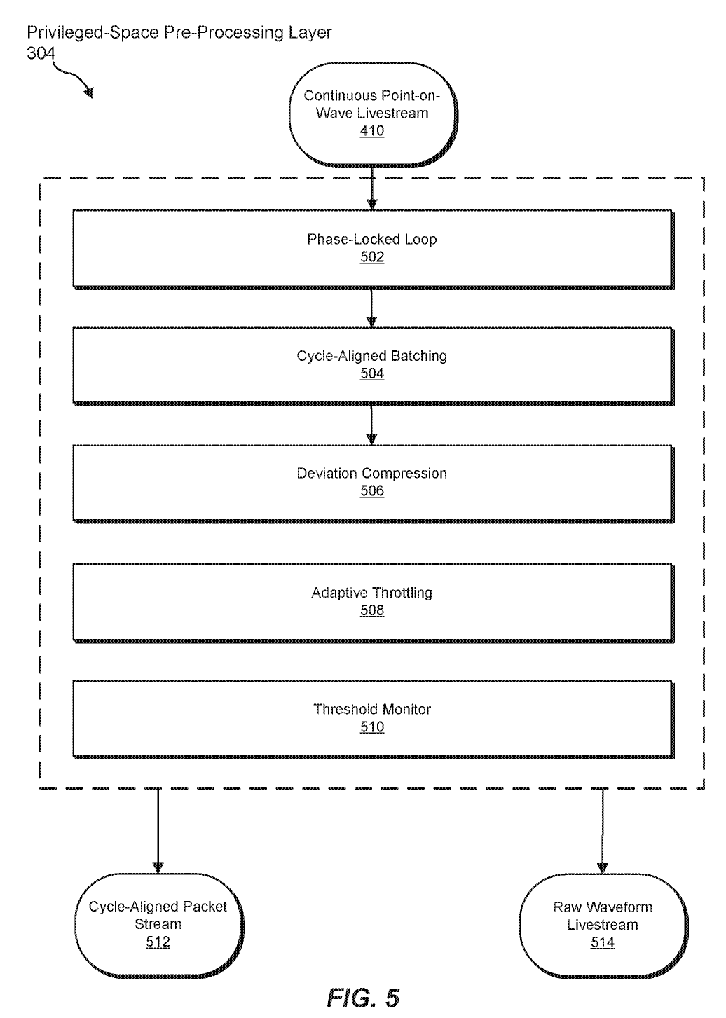

FIG. 5 illustrates an exemplary implementation of privileged-space pre-processing layer 304 that facilitates and/or supports deterministic processing of a CPOW livestream prior to user-space multi-modal processing. In some examples, privileged-space pre-processing layer 304 in FIG. 5 may include and/or involve certain devices, components, configurations, and/or features that perform and/or provide functionalities that are similar and/or identical to those described above in connection with any of FIGS. 1-4. As illustrated in FIG. 5, privileged-space pre-processing layer 304 may include and/or involve a phase-locked loop (PLL) 502, cycle-aligned batching 504, deviation compression 506, adaptive throttling 508, a threshold monitor 510, a cycle-aligned packet stream 512, and/or a raw waveform livestream 514.

In some examples, privileged-space pre-processing layer 304 may run in a deterministic environment with guaranteed scheduling priority such that processing keeps pace with an incoming continuous waveform data stream without data loss. In one example, privileged-space pre-processing layer 304 may ingest CPOW livestream 410 and then process the CPOW livestream in privileged space (e.g., kernel space, a microcontroller environment, and/or a field-programmable gate array (FPGA) environment) to provide timing-coherent, physics-aligned handling of waveform samples.

In some examples, PLL 502 may track an alternating current (AC) fundamental component with sub-sample zero-crossing precision and provide a single timing reference that serves multiple functions from a single deterministic source. In one example, PLL 502 may provide the timing reference used by cycle-aligned batching 504 to organize the raw sample stream into cycle-aligned groupings corresponding to individual electrical cycles, thereby creating physics-aligned boundaries that are maintained for downstream processing. In another example, PLL 502 may provide a phase reference used by deviation compression 506 to compute cycle residuals, and a carrier reference used by downstream demodulation 612 for carrier removal. Generating the PLL timing reference in privileged space guarantees coherence across all served functions with deterministic timing that user-space generation may not reliably provide.

In some examples, deviation compression 506 may compute a PLL-referenced residual for each cycle and apply lossless compression to reduce data volume while preserving waveform fidelity. In one example, deviation compression 506 may achieve compression ratios (e.g., on the order of 10:1 to 15:1) by representing each cycle relative to the PLL-based phase reference while retaining the ability to reconstruct the waveform without information loss.

In some examples, adaptive throttling 508 may provide context-aware rate control when downstream bandwidth and/or storage is constrained. Additionally or alternatively, threshold monitor 510 may perform fast event flagging directly in privileged space to support low-latency detection of PQ events (e.g., sub-cycle detection of sags, swells, and/or transient events) without waiting for downstream user-space processing.

In some examples, privileged-space pre-processing layer 304 may emit multiple concurrent output streams derived from the same ingested waveform data. In one example, privileged-space pre-processing layer 304 may output a cycle-aligned packet stream 512 that includes physics-structured, cycle-aligned data suitable for standards-compliant computation and/or other cycle-based analysis. Additionally or alternatively, privileged-space pre-processing layer 304 may output a raw waveform livestream 514 as a passthrough representation that preserves full sample-rate data for arbitrary downstream digital signal processing. In this example, cycle-aligned packet stream 512 and raw waveform livestream 514 are derived from the same acquisition and are available simultaneously for downstream processing such that multiple analysis modalities are able to operate concurrently, each selecting which representation to consume based on the requirements of that modality, without committing to a single analysis approach at capture time.

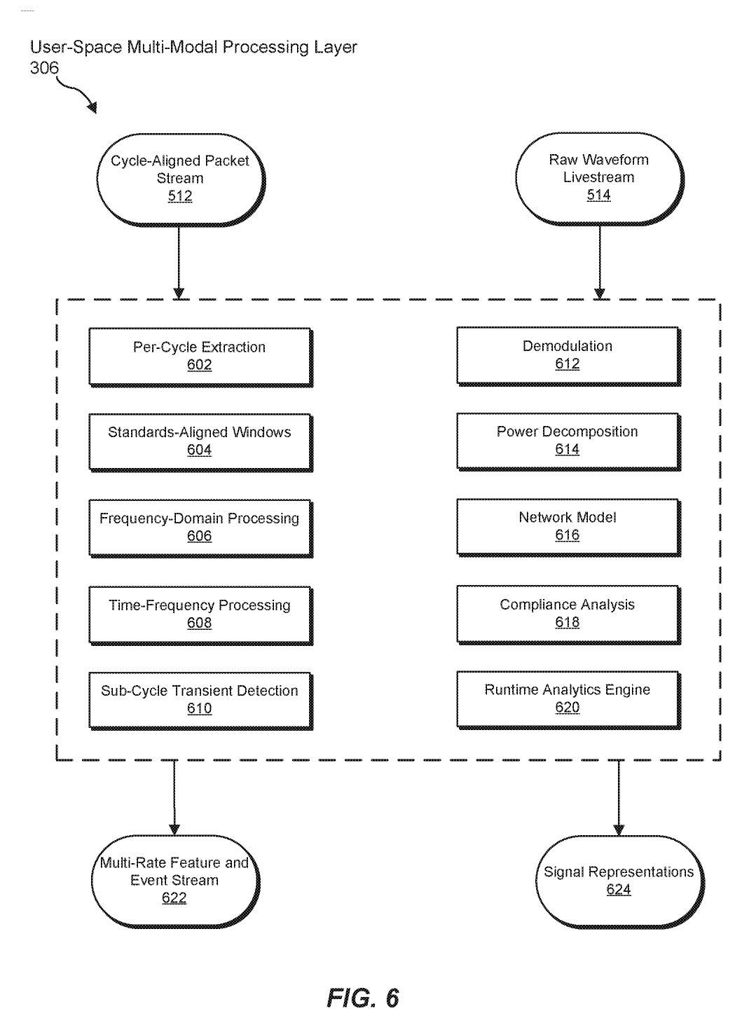

FIG. 6 illustrates an exemplary implementation of user-space multi-modal processing layer 306 that facilitates and/or supports concurrent analysis modalities operating on waveform data derived from a single continuous acquisition. In some examples, user-space multi-modal processing layer 306 in FIG. 6 may include and/or involve certain devices, components, configurations, and/or features that perform and/or provide functionalities that are similar and/or identical to those described above in connection with any of FIGS. 1-5. As illustrated in FIG. 6, user-space multi-modal processing layer 306 may include and/or involve per-cycle extraction 602, standards-aligned windows 604, frequency-domain processing 606, time-frequency processing 608, sub-cycle transient detection 610, demodulation 612, power decomposition 614, network model processing 616, compliance analysis 618, a runtime analytics engine 620, a multi-rate feature and event stream 622, and signal representations 624.

In some examples, user-space multi-modal processing layer 306 may ingest one or more privileged-space outputs (e.g., cycle-aligned packet stream 512 and/or raw waveform livestream 514) and execute multiple analysis paths concurrently on the same continuous data stream. In one example, no analysis path is locked to a single input representation, and each analysis path independently selects whether to consume cycle-aligned packet stream 512, raw waveform livestream 514, or both, based on the requirements of that analysis path. In this example, additional analysis modalities may be added to user-space multi-modal processing layer 306 without modifying existing analysis paths and without recapturing the power waveform data.

In some examples, per-cycle extraction 602 may involve computing cycle-rate measurements and events, such as root-mean-square (RMS) voltage and RMS current, frequency estimation, and sag/swell/interruption detection. In one example, by doing so, per-cycle extraction 602 may produce latency-sensitive power-quality information at an electrical-cycle rate (e.g., approximately 16.7 milliseconds at 60 Hz). In some examples, standards-aligned windows 604 may implement standards-compliant computations using standards-defined windowing and/or aggregation. For example, standards-aligned windows 604 may implement IEC 61000-4-7 harmonic analysis using 10/12-cycle DFT windows and/or IEC 61000-4-30 aggregation across multiple time tiers (e.g., including 5 Hz, 10-minute, and/or 2-hour intervals) to produce standards-compliant measurement results. Together with sub-cycle transient detection 610 operating at full sample-rate resolution, the plurality of concurrent analysis modalities collectively derive measurements across time scales spanning at least six orders of magnitude from the same uninterrupted data stream, from sub-cycle transients of less than one millisecond through multi-hour compliance aggregation windows, including time scales not anticipated at the time of system design or data acquisition.

In some examples, frequency-domain processing 606 may involve computing spectral representations from waveform data using sliding-window fast Fourier transform (FFT) and/or short-time Fourier transform (STFT). Such spectral representations may include and/or represent spectral density estimation and/or inter-harmonic detection with configurable window size and/or overlap. In some examples, time-frequency processing 608 may involve computing time-localized spectral representations using wavelet transforms (whether continuous or discrete) to support multi-resolution analysis and/or event detection. Such multi-resolution analysis and/or event detection may be able to capture non-stationary phenomena that could otherwise be missed by fixed-window methods.

In some examples, sub-cycle transient detection 610 may involve operating at full sample-rate resolution on waveform data to detect and/or characterize impulsive and/or oscillatory transient events at sub-cycle timescales. In one example, demodulation 612 may involve performing Hilbert transform and/or in-phase/quadrature (I-Q) envelope extraction with carrier removal referenced to a phase reference. In this example, demodulation 612 may facilitate and/or support analysis of amplitude-modulation and/or frequency-modulation patterns present in the waveform data.

In some examples, power decomposition 614 may implement and/or provide power-component separation (e.g., decomposition of apparent power into fundamental and non-fundamental contributions) to distinguish distortion-related components from fundamental power components. In one example, network model processing 616 may involve performing topology-aware computation using a network model and/or graph-based analysis, such as power-flow computation across a monitored network topology with per-harmonic solving and optional hardware acceleration for multi-node analysis. Additionally or alternatively, compliance analysis 618 may involve evaluating measured quantities against one or more standards and/or configurable rulesets (e.g., IEEE 519 and/or EN 50160), including real-time trending and/or automated reporting.

In some examples, runtime analytics engine 620 may provide a framework for deploying user-defined and/or AI-generated analysis algorithms at runtime without modifying a core processing pipeline. In such examples, runtime analytics engine 620 may accept structured queries and/or produce custom transforms or outputs based at least in part on the ingested waveform data and/or derived representations.

In some examples, user-space multi-modal processing layer 306 may generate and/or output a multi-rate feature and event stream 622 that includes structured, standards-grounded measurements and/or detected events across multiple time scales. Additionally or alternatively, user-space multi-modal processing layer 306 may generate and/or output signal representations 624 that include spectral, time-frequency, envelope, and/or model-residual data suitable for downstream SEAC layer 308.

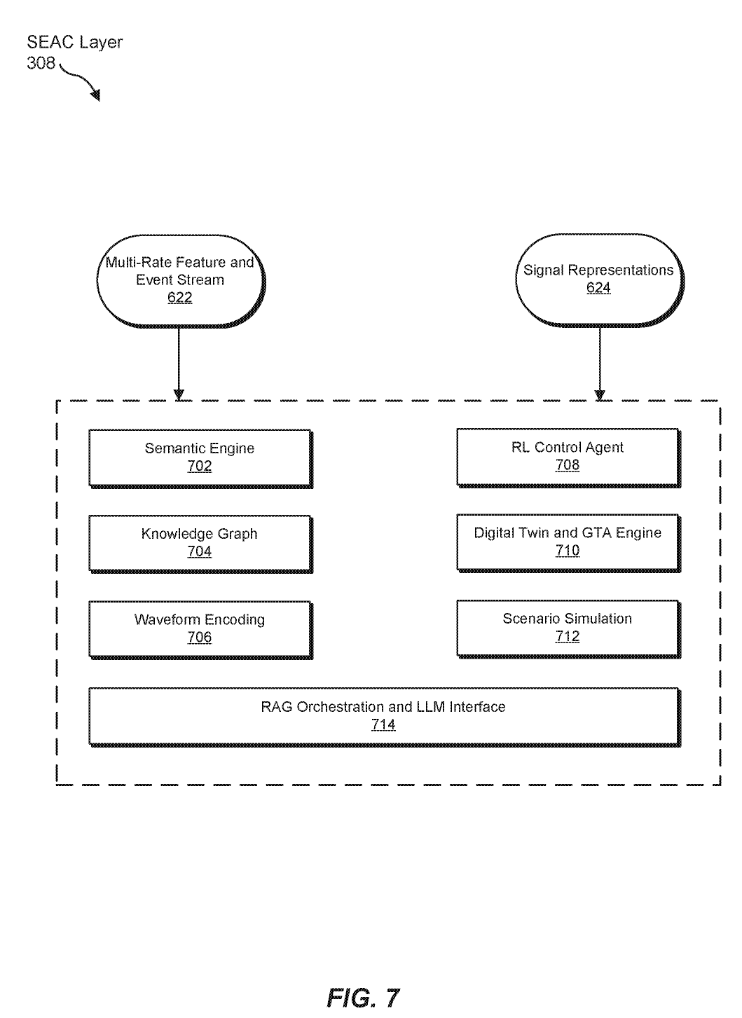

FIG. 7 illustrates an exemplary implementation of SEAC layer 308 that facilitates and/or supports semantic interpretation, decision support, and/or constrained control based on waveform-derived data products. In some examples, SEAC layer 308 in FIG. 7 may include and/or involve certain devices, components, configurations, and/or features that perform and/or provide functionalities that are similar and/or identical to those described above in connection with any of FIGS. 1-6. As illustrated in FIG. 7, SEAC layer 308 may include and/or involve a semantic engine 702, a knowledge graph 704, waveform encoding 706, a reinforcement learning (RL) control agent 708, a digital twin and graph trace analysis (GTA) engine 710, scenario simulation 712, and/or a retrieval-augmented generation (RAG) orchestration and large language model (LLM) interface 714.

In some examples, SEAC layer 308 may ingest structured features, measurements, events, and/or signal representations produced by upstream processing. For example, SEAC layer 308 may ingest multi-rate feature and event stream 622 and/or signal representations 624 from user-space multi-modal processing layer 306. In such examples, SEAC layer 308 may process the ingested data to generate enriched results that add interpretive context, multi-device correlation, and/or facility-level understanding. Additionally or alternatively, SEAC layer 308 may generate outputs that include advisory recommendations, control intents, and/or bounded execution plans.

In some examples, semantic engine 702 may generate standards-grounded assertions from measured features, including mapping computed measurements and/or detected events into domain-relevant statements that are traceable to underlying signal-derived evidence. Additionally or alternatively, semantic engine 702 may correlate events across multiple devices and/or time windows to provide multi-device context for interpretation of PQ conditions.

In some examples, knowledge graph 704 may maintain an event-driven topology that represents relationships among detected events, equipment states, and/or operational context. In one example, knowledge graph 704 may store causal and/or temporal edges that preserve ordering and/or dependency of events over time. Additionally or alternatively, knowledge graph 704 may support queries that traverse relationships between waveform-derived events and modeled system context.

In some examples, waveform encoding 706 may map signal representations into vector embeddings suitable for similarity-based retrieval. In such examples, waveform encoding 706 may enable pattern matching against known event signatures and/or historical waveform records. In one example, such pattern matching may include and/or involve retrieving prior events that are similar in waveform shape, spectral signature, time-frequency content, and/or other waveform-derived representations.

In some examples, RL control agent 708 may generate advisory recommendations and/or closed-loop control decisions that optimize operational setpoints within physics-defined constraints and/or explicit authority boundaries. Additionally or alternatively, scenario simulation 712 may generate and/or simulate “what-if” scenarios using physics-based and/or learned models to support planning, training, and/or rare-event analysis prior to the execution of control actions.

In some examples, digital twin and GTA engine 710 may reconcile model predictions against measured reality. Additionally or alternatively, digital twin and GTA engine 710 may generate residuals indicative of mismatch between expected and observed behavior. In such examples, digital twin and GTA engine 710 may localize anomalies to specific network locations and/or equipment by analyzing residual structure over time. In one example, digital twin and GTA engine 710 may provide physics-grounded context for downstream interpretation and/or decision support.

In some examples, RAG orchestration and LLM interface 714 may coordinate one or more SEAC functions by routing user queries and/or system intents into bounded, auditable execution pipelines. In one example, RAG orchestration and LLM interface 714 may select among approved analytical and/or control tools based on user intent, system context, and/or available data. Additionally or alternatively, RAG orchestration and LLM interface 714 may constrain invocation of calls and/or triggers such that tool-augmented reasoning and/or downstream actions occur within defined safety envelopes.

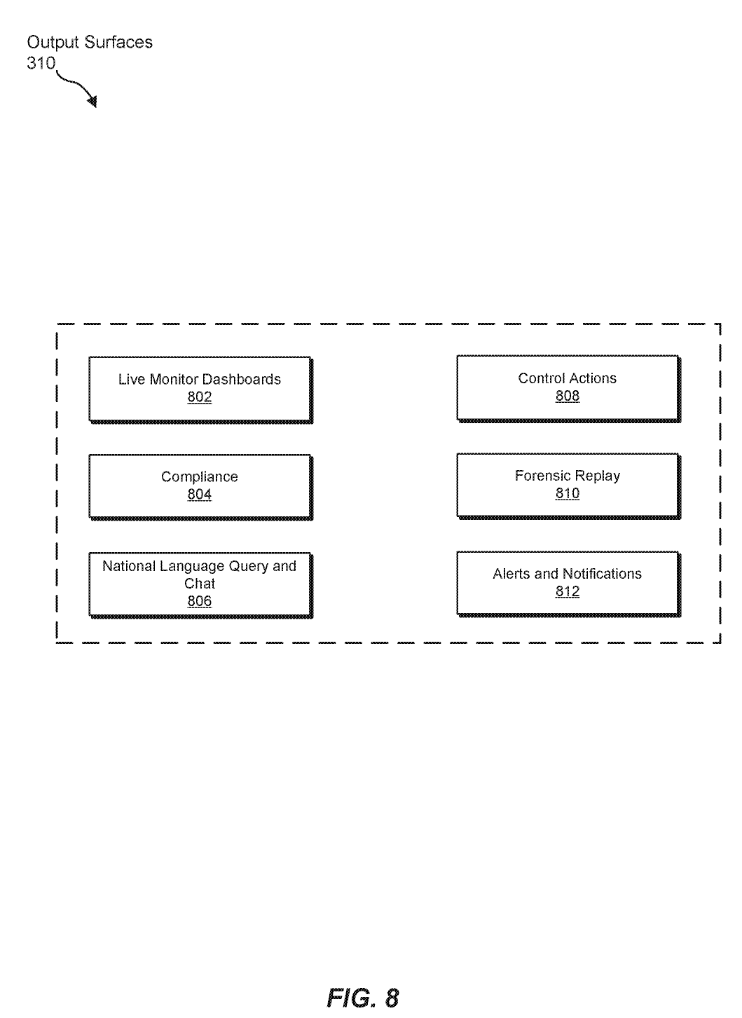

FIG. 8 illustrates an exemplary implementation of output surfaces 310 that facilitate and/or support presentation, delivery, and/or interaction with results produced by upstream processing and/or semantic enrichment. In some examples, output surfaces 310 in FIG. 8 may include and/or involve certain devices, components, configurations, and/or features that perform and/or provide functionalities that are similar and/or identical to those described above in connection with any of FIGS. 1-7. As illustrated in FIG. 8, output surfaces 310 may include and/or involve live monitoring dashboards 802, compliance reporting 804, natural language query and chat 806, control actions 808, forensic replay 810, and/or alerts and notifications 812.

In some examples, output surfaces 310 may ingest structured measurements, features, and/or events (e.g., multi-rate feature and event stream 622) and/or enriched results, recommendations, and/or bounded execution plans produced by SEAC layer 308. In such examples, output surfaces 310 may transform the ingested information into one or more human-consumable and/or machine-consumable deliverables. Additionally or alternatively, output surfaces 310 may provide one or more interaction mechanisms for investigation, reporting, and/or operational response.

In some examples, live monitoring dashboards 802 may provide near real-time visualization of selected measurements, derived features, detected events, and/or interpretations. For example, live monitoring dashboards 802 may present facility-level and/or device-level statuses based at least in part on the physics-grounded outputs of upstream layers. Additionally or alternatively, compliance reporting 804 may involve generating reports and/or summaries associated with one or more power-quality standards and/or configurable rulesets. For example, compliance reporting 804 may involve producing compliance assessments derived from standards-aligned computations performed upstream.

In some examples, natural language query and chat 806 may involve providing an operator-facing interface for submitting questions and/or investigative requests. In such examples, natural language query and chat 806 may involve receiving responses grounded in available structured features, events, and/or semantic outputs. In one example, natural language query and chat 806 may involve presenting explanations, summaries, and/or supporting artifacts derived from upstream semantic enrichment and/or retrieval functions.

In some examples, control actions 808 may involve providing an interface for presenting advisory recommendations and/or enabling execution of control intents generated upstream within defined authority boundaries. In such examples, control actions 808 may involve exposing control-related outputs for review and/or downstream integration. For example, control actions 808 may involve enabling operational workflows to accept, reject, and/or apply recommended actions (e.g., by AI and/or a human operator).

In some examples, forensic replay 810 may involve providing an interface for retrospective investigation by enabling selection and/or review of historical waveform-derived artifacts. For example, forensic replay 810 may involve replaying relevant time windows and correlation of events and features over time. Additionally or alternatively, alerts and notifications 812 may involve providing event-driven deliverables (e.g., alarms, notifications, and/or messages) based at least in part on detected conditions, compliance thresholds, and/or inferred interpretations produced upstream. For example, alerts and notifications 812 may involve routing such event-driven deliverables to operators and/or external systems for timely response.

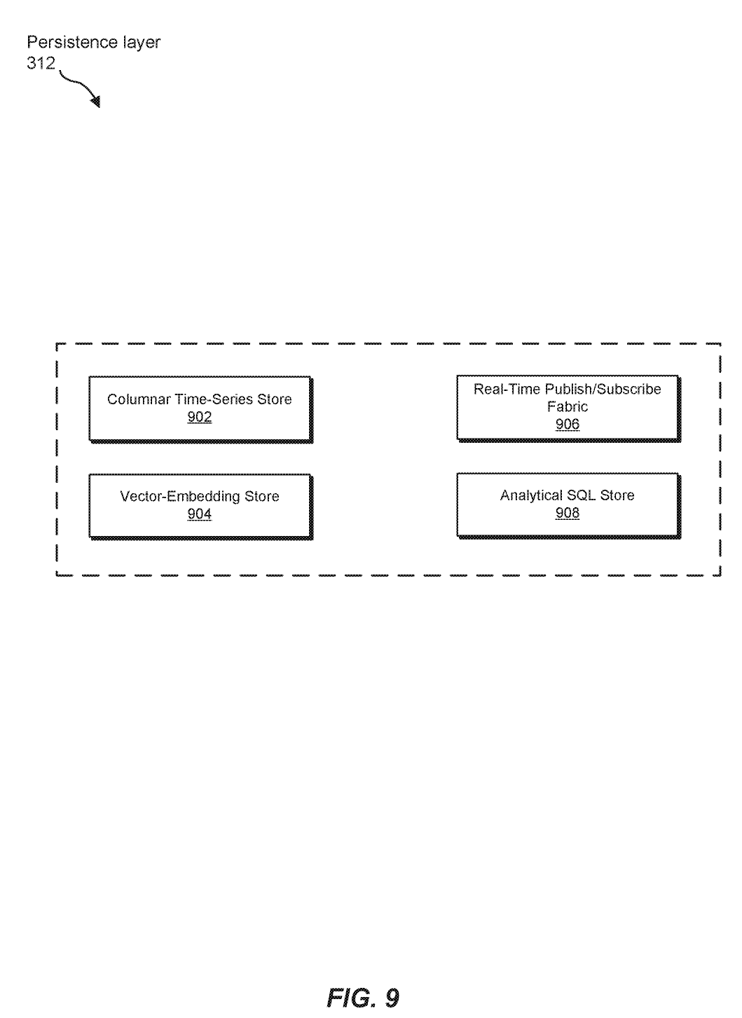

FIG. 9 illustrates an exemplary implementation of persistence layer 312 that facilitates and/or supports storage, retrieval, and/or distribution of waveform-derived data products for replay, audit, historical analysis, and/or downstream analytics. In some examples, persistence layer 312 in FIG. 9 may include and/or involve certain devices, components, configurations, and/or features that perform and/or provide functionalities that are similar and/or identical to those described above in connection with any of FIGS. 1-8. As illustrated in FIG. 9, persistence layer 312 may include and/or involve a columnar time-series store 902, a vector-embedding store 904, a real-time publish/subscribe fabric 906, and/or an analytical SQL store 908.

In some examples, persistence layer 312 may ingest one or more waveform streams, packaged waveform segments, derived indicators, structured measurements, features, events, representations, enriched results, and/or control-related artifacts produced by upstream layers. In such examples, persistence layer 312 may store and/or index the ingested data in a way that supports multiple access patterns, including bulk analytics, similarity-based retrieval, real-time distribution, and ad-hoc investigation.

In some examples, columnar time-series store 902 may store time-aligned waveform-derived data in a columnar format (e.g., Parquet) suitable for bulk retrieval and large-scale analytical processing. In such examples, columnar time-series store 902 may be used to support historical analysis, replay, compliance evidence generation, and/or model training and evaluation using archived continuous data.

In some examples, vector embedding store 904 may store vector embeddings derived from waveform representations and/or semantic outputs (e.g., embeddings produced from spectral, time-frequency, envelope, and/or residual representations). In such examples, vector embedding store 904 may support similarity search and retrieval workflows (e.g., LanceDB) that enable identification of prior events and/or waveform patterns that are similar to a current event under investigation.

In some examples, real-time publish/subscribe fabric 906 may distribute selected waveform-derived streams and/or derived outputs to downstream subscribers in real time. In one example, real-time publish/subscribe fabric 906 may facilitate and/or support network-wide distribution (e.g., Zenoh) such that processing nodes, operator-facing interfaces, and/or external systems subscribe to one or more streams without requiring tight coupling to a single storage backend.

In some examples, analytical SQL store 908 may facilitate and/or support ad-hoc analytical queries over persisted datasets. For example, DuckDB may enable investigation workflows that join and/or filter measurements, events, and metadata across time windows. In such examples, persistence layer 312 may match storage formats to access patterns. For example, DuckDB may use columnar storage for bulk waveform analytics, vector storage for semantic retrieval, publish/subscribe for real-time streaming distribution, and/or SQL-oriented storage for interactive investigation and/or reporting.

In some examples, a system may be configured to continuously acquire and/or output power waveform data as an uninterrupted point-on-wave data stream with no observation gaps. In such examples, the uninterrupted data stream may include substantially every digitized sample acquired from an electrical power system across multiple measurement channels, including multiple voltage channels and multiple current channels, with the samples acquired at a fixed sampling rate and resolution. For example, the system may sample at approximately 32 kHz per channel with approximately 24-bit resolution and may concurrently acquire approximately seven channels including three voltage channels, three current channels, and a neutral channel. By preserving every sample of every electrical cycle in the uninterrupted data stream, the system may enable downstream processing to analyze any time window retroactively at full sample-rate fidelity, including time windows that were not anticipated at the time of acquisition, rather than relying on triggered and/or windowed capture that can miss transient precursors and inter-event context.

In some examples, the system may pre-process the uninterrupted data stream to produce at least two concurrent output representations, such as a cycle-aligned representation organized by electrical-cycle boundaries and a raw waveform representation that preserves full sample-rate data. In one example, the cycle-aligned representation may be emitted and/or provided as a packetized stream of per-cycle data objects aligned to AC physics such that each data object corresponds to one electrical cycle (or another cycle-based grouping), and each data object may include cycle boundary metadata and/or one or more cycle-level values derived from the samples. In this example, the raw waveform representation may be emitted and/or provided as a passthrough livestream that preserves the original sample sequence, thereby supporting arbitrary digital signal processing in which analysis windows may be selected independently of cycle boundaries. In some examples, providing both representations concurrently may enable standards-oriented analysis to consume cycle-aligned data while transient-oriented and exploratory analyses consume raw samples.

In some examples, the pre-processing may be executed and/or performed in a deterministic execution environment with guaranteed scheduling priority sufficient to keep pace with the uninterrupted data stream without data loss. For example, the deterministic execution environment may include and/or represent an operating system kernel context (including kernel-resident packet-processing and data-path execution), an extended Berkeley Packet Filter (eBPF) program, microcontroller firmware, and/or a field-programmable gate array (FPGA) implementation. In such examples, the deterministic execution environment may reduce jitter and latency variation in time-sensitive computations (e.g., cycle boundary identification, event flagging, and rate control) and may complete bounded-latency, cycle-coherent transforms prior to any user-space scheduling effects, thereby enabling downstream processing to receive structured outputs that are already aligned to AC physics.

In some examples, the system may derive the cycle-aligned representation and the raw waveform representation from the same acquisition of the power waveform data and may make both representations available simultaneously to a plurality of concurrent analysis modalities. In such examples, each analysis modality may independently select which representation to consume (e.g., cycle-aligned, raw waveform, or both) based at least in part on the requirements of the corresponding analysis modality. For example, a standards-oriented modality may consume cycle-aligned data to maintain precise cycle boundary alignment for aggregation, while a transient detection modality may consume raw samples at full resolution to capture sub-cycle phenomena. Accordingly, the system may avoid committing to any single analysis modality at capture time and may support parallel investigation paths that operate on the same underlying physical record.

In some examples, the system may execute multiple concurrent analysis modalities that operate simultaneously on the uninterrupted data stream. For example, per-cycle extraction may compute cycle-rate measurements such as RMS voltage and RMS current, frequency estimation, and sag/swell/interruption detection from the cycle-aligned representation. Additionally or alternatively, standards-aligned windowed analysis may involve computing standards-compliant measurements using standards-defined windows and aggregation intervals, including harmonic measurements using 10/12-cycle windows and/or multi-tier aggregations across short and long intervals for reporting and trending. Additionally or alternatively, frequency-domain processing may involve computing spectral representations from the raw waveform representation using sliding-window FFT and/or STFT with configurable window length and overlap, and time-frequency processing may involve computing time-localized spectral representations using wavelet transforms to identify non-stationary events.

In some examples, sub-cycle transient detection may involve operating at full sample-rate resolution on the raw waveform representation to detect and characterize impulsive and/or oscillatory transients. In such examples, demodulation may involve performing envelope extraction (e.g., Hilbert transform and/or I-Q extraction) directed to a phase reference for extracting amplitude and/or frequency modulation patterns. Additionally or alternatively, power decomposition may involve separating apparent power into fundamental and non-fundamental contributions to distinguish distortion-related components from fundamental components. In one example, network model processing may involve performing topology-aware power-flow computation and/or graph-based analysis including per-harmonic solving and optional hardware acceleration. In this example, compliance analysis may involve evaluating measured quantities against one or more power-quality standards (e.g., IEEE 519, EN 50160, and/or IEC-based rulesets) with trending and/or automated reporting.

In some examples, one or more additional analysis modalities may be addable to the plurality of concurrent analysis modalities without modifying any existing analysis modalities and without recapturing the power waveform data. In such examples, the uninterrupted data stream may function as a persistent, modality-agnostic source from which new analysis paths are introduced at any time (e.g., after a disturbance has occurred). For example, an operator and/or an automated agent may introduce a new analysis modality to investigate a particular class of events, and the system may apply that new modality to historical intervals by replaying stored waveform data without requiring any changes to the acquisition configuration or re-running the measurement.

In some examples, the plurality of concurrent analysis modalities may collectively derive measurements across time scales spanning at least three orders of magnitude from the uninterrupted data stream. In one example, such measurements may include and/or represent sub-cycle measurements at a time scale shorter than one electrical cycle (e.g., microsecond-to-millisecond transient features and/or sub-cycle envelope variations) and multi-cycle aggregated measurements at a time scale of at least one minute (e.g., rolling compliance statistics and/or aggregated PQ indices). In some examples, the architecture may further support additional standards-oriented and/or configurable aggregation tiers (e.g., cycle-based windows, multi-second windows, multi-minute windows, and multi-hour windows) such that short-interval and longer-interval compliance and trending results are all derived from the same uninterrupted source rather than being stitched together from triggered captures.

In some examples, the system may include and/or represent a runtime analytics engine that accepts and/or executes user-defined or machine-generated analysis algorithms at runtime without modifying any of the concurrent analysis modalities and without recompiling a core processing pipeline. In such examples, the runtime analytics engine may accept structured queries and/or algorithm definitions that specify input signals, processing steps, and/or output formats. In one example, the runtime analytics engine may then execute the requested transformations on the uninterrupted data stream and/or derived representations. In this example, the runtime analytics engine may enable rapid deployment of new transforms and/or derived metrics to support investigation, compliance, and control use cases while maintaining continuity of the underlying data stream.

In some examples, the runtime analytics engine may be deployed across multiple processing tiers that execute a common algorithmic definition. For example, the multiple processing tiers may include and/or represent a sensor node, an edge gateway, a compute server, and/or a cloud-based processing environment. In this example, a common algorithmic definition may pushed to different locations depending on the corresponding latency, resource availability, and/or fidelity requirement of the different processing tiers. In one example, the system may execute a latency-sensitive portion of an algorithm at an edge tier while executing computationally intensive correlation and/or batch analytics at a server or cloud tier while maintaining the same functional algorithmic definition across all the tiers.

In some examples, the system may implement a semantic enrichment layer that operates on structured features and signal representations produced by the plurality of concurrent analysis modalities. For example, the semantic enrichment layer may include and/or represent a semantic engine that generates standards-grounded assertions from measured features, such as mapping measurements and detected events into traceable, domain-relevant statements. Additionally or alternatively, the semantic enrichment layer may include and/or represent a knowledge graph that maintains an event-driven topology with causal and/or temporal edges linking detected events, equipment state, and/or operational contexts.

In some examples, the semantic enrichment layer may include and/or represent a waveform encoder that maps signal representations into vector embeddings for similarity-based retrieval against historical waveform records and/or known event signatures. Additionally or alternatively, the semantic enrichment layer may include and/or represent a RAG orchestration layer that provides tool-augmented reasoning over the structured features using bounded, auditable execution pipelines in which the RAG orchestration layer selects among approved tools and/or constrains invocation based at least in part on authority boundaries and/or safety envelopes.

In some examples, the system may implement a PLL that tracks an AC fundamental of the power waveform data and/or provides a single timing reference that serves multiple downstream functions. In one example, the PLL may provide a phase-coherent estimate of fundamental frequency and phase. In this example, the PLL may identify electrical-cycle boundaries with sub-sample timing precision.

In some examples, the single timing reference may serve to define electrical-cycle boundaries for generating the cycle-aligned representation, supply a phase reference for deviation-based compression of the power waveform data (e.g., compression that represents samples as deviations from a PLL-referenced waveform), and/or supply a carrier reference for demodulation of the power waveform data. In one example, the single timing reference may enable multiple processing functions to share a common, physics-grounded reference.

In some examples, the PLL may execute in a deterministic execution environment with guaranteed scheduling priority such that the single timing reference maintains coherence across the plurality of downstream functions served by the single timing reference. In one example, deterministic execution of the PLL may involve reducing timing jitter that would otherwise accumulate through scheduling variation. Additionally or alternatively, deterministic execution of the PLL may ensure that cycle boundary definitions, compression reference generation, and/or demodulation reference generation remain phase-consistent and/or timing-coherent across the system. As a result, concurrent multi-modal processing may operate on shared, physics-aligned timing to reduce re-alignment overhead and/or to improve consistency between outputs generated by different modalities.

In some examples, the various apparatuses, devices, and systems described in connection with FIGS. 1-9 may include and/or represent one or more additional circuits, devices, components, and/or features that are not necessarily illustrated and/or labeled in FIGS. 1-9. For example, the apparatuses, devices, and systems illustrated in FIGS. 1-9 may also include and/or represent additional analog and/or digital circuitry, onboard logic, transistors, RF transmitters, RF receivers, transceivers, antennas, resistors, capacitors, diodes, inductors, switches, registers, flipflops, digital logic, connections, traces, buses, semiconductor (e.g., silicon) devices and/or structures, processing devices, storage devices, circuit boards, sensors, packages, substrates, housings, fiber optics, combinations or variations of one or more of the same, and/or any other suitable components. In certain implementations, one or more of these additional circuits, components, and/or features may be inserted and/or applied between any of the existing circuits, components, and/or features illustrated in FIGS. 1-9 consistent with the aims and/or objectives described herein. Accordingly, the couplings and/or connections described with reference to FIGS. 1-9 may be direct connections with no intermediate components, devices, and/or nodes or indirect connections with one or more intermediate components, devices, and/or nodes.

In some examples, the phrase “to couple” and/or the term “coupling”, as used herein, may refer to a direct connection and/or an indirect connection. For example, a direct coupling between two components constitutes and/or represents a coupling in which those two components are directly connected to each other by a single node that provides continuity from one of those two components to the other. In other words, the direct coupling excludes and/or omits any additional components between those two components.

Additionally or alternatively, an indirect coupling between two components constitutes and/or represents a coupling in which those two components are indirectly connected to each other by multiple nodes that fail to provide continuity from one of those two components to the other. In other words, the indirect coupling includes and/or incorporates at least one additional component between those two components. In some examples, one or more components and/or features illustrated in FIGS. 1-9 may be excluded and/or omitted from the various apparatuses, devices, and/or systems described in connection with FIGS. 1-9.

FIG. 10 is a flow diagram of an exemplary method 1000 for energy and PQ-aware compute, analysis, and control. Method 1000 may include the step of outputting, by a sensor included in the computing system, power waveform data representative of measurements from an electrical power system (1010). Step 1010 may be performed in a variety of ways, including any of those described above in connection with FIGS. 1-9. For example, a sensor included in a computing system may output power waveform data representative of measurements from an electrical power system.

Method 1000 may also include the step of executing, by circuitry included in the computing system, a privileged-space component to enforce a policy in connection with the electrical power system based at least in part on the power waveform data (1020). Step 1020 may be performed in a variety of ways, including any of those described above in connection with FIGS. 1-9. For example, circuitry communicatively coupled to the sensor may execute a privileged-space component that (1) extracts at least one power-quality indicator of the electrical power system from the power waveform data and (2) enforces, based at least in part on the power-quality indicator, a policy in connection with the electrical power system by performing at least one action in connection with the electrical power system or the circuitry.

Many other devices or subsystems may be connected to the computing systems and apparatuses described herein. Conversely, all of the components and devices illustrated in the systems and apparatuses need not be present to practice the embodiments described and/or illustrated herein. The devices and subsystems referenced above may also be interconnected in different ways from those shown in the figures.

The computing systems and apparatuses may also employ any number of software, firmware, and/or hardware configurations. For example, one or more of the exemplary embodiments disclosed herein may be encoded as a computer program (also referred to as computer software, software applications, computer-readable instructions, or computer control logic) on a computer-readable medium. The term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives and floppy disks), optical-storage media (e.g., Compact Disks (CDs) and Digital Video Disks (DVDs)), electronic-storage media (e.g., solid-state drives and flash media), and other distribution systems.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware, software, or firmware (or any combination thereof) configurations. In addition, any disclosure of components contained within other components should be considered exemplary in nature since many other architectures can be implemented to achieve the same functionality.

In some examples, all or a portion of system 100 in FIG. 1 may represent portions of a cloud-computing or network-based environment. Cloud-computing and network-based environments may provide various services and applications via the Internet. These cloud-computing and network-based services (e.g., software as a service, platform as a service, infrastructure as a service, etc.) may be accessible through a web browser or other remote interface. Various functions described herein may also provide network switching capabilities, gateway access capabilities, network security functions, content caching and delivery services for a network, network control services, and/or other networking functionality.

In addition, the circuitry described herein may transform data, physical devices, and/or representations of physical devices from one form to another. Additionally or alternatively, one or more of the modules recited herein may transform a processor, volatile memory, non-volatile memory, and/or any other portion of a physical computing device from one form to another by executing on the computing device, storing data on the computing device, and/or otherwise interacting with the computing device.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the instant disclosure. The embodiments disclosed herein should be considered in all respects illustrative and not restrictive. Reference should be made to the appended claims and their equivalents in determining the scope of the instant disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A system comprising:
a sensor configured to output power waveform data representative of measurements from an electrical power system; and
circuitry configured to execute, in a privileged space, a component that:
extracts at least one power-quality indicator of the electrical power system from the power waveform data; and
enforces, based at least in part on the power-quality indicator, a policy in connection with the electrical power system by performing at least one action in connection with the electrical power system or the circuitry.

2. The system of claim 1, wherein the circuitry comprises a hardware-based processor configured to implement an operating system (OS) kernel that executes the component.

3. The system of claim 1, wherein the component comprises an extended Berkeley Packet Filter (eBPF) program.

4. The system of claim 1, wherein the component is attached to an eXpress Data Path (XDP) hook point or Traffic Control (TC) hook point such that the circuitry:
associates an XDP or TC mechanism to a network interface; and
automatically invokes the XDP or TC mechanism in response to the power waveform data arriving at the network interface.

5. The system of claim 1, wherein:
the sensor is further configured to output additional power waveform data representative of additional measurements from the electrical power system; and
the component further routes the additional power waveform data to user space via an Address Family eXpress Data Path (AFXDP) socket path.

6. The system of claim 5, wherein the user space further:
receives the additional power waveform data via direct streaming; and
feeds the additional waveform data to a target for processing or storage in connection with the policy.

7. The system of claim 1, wherein the component further routes the power-quality indicator to user space via at least one shared data structure.

8. The system of claim 7, wherein the user space further:
receives the power-quality indicator via the shared data structure; and
feeds the power-quality indicator to an application that analyzes a power quality of the electrical power system based at least in part on the power-quality indicator.

9. The system of claim 7, wherein the user space further:
receives the power-quality indicator from the component in response to detection of a power-quality violation; and
feeds the power-quality indicator to an application that analyzes a power quality of the electrical power system based at least in part on the power-quality indicator.

10. The system of claim 9, further comprising an interrupt configured to signal arrival of the power waveform data, wherein the component is further configured to:
analyze the power waveform data for the power-quality violation in response to an event triggered by the interrupt;
detect the power-quality violation based at least in part on the analysis of the power waveform data.

11. The system of claim 1, wherein the component further implements a feedback loop for dynamically adaptive sampling of the power waveform data to balance resolution versus resource usage.

12. The system of claim 1, wherein the component further changes an operating state of at least one compute resource by at least one of:
executing an Advanced Configuration and Power Interface (ACPI) method call to adjust a power state of a hardware-based processor included in the circuitry; or
configuring a frequency scaling setting of a hardware-based processor included in the circuitry.

13. The system of claim 1, wherein the action comprises at least one of:
changing an operating state of at least one compute resource of the circuitry; or
changing an operating state of at least one energy resource of the electrical power system.

14. The system of claim 1, wherein the circuitry is further configured to implement an artificial intelligence (AI) model that:
analyzes a state of the electrical power system based at least in part on the power-quality indicator; or
performs decision-making in connection with the enforcement of the policy based at least in part on the power-quality indicator.

15. The system of claim 1, wherein the circuitry is further configured to implement an artificial intelligence (AI) model that directs the component in the privileged space to:
extract the power-quality indicator from the power waveform data; or
enforce the policy in connection with the electrical power system.

16. The system of claim 1, wherein the privileged space comprises at least one of:
kernel space;
a virtual machine environment; or
firmware.

17. The system of claim 1, further comprising an interface configured to:
communicatively couple the sensor to the circuitry; and
transfer the power waveform data from the sensor to the circuitry over a network using Transmission Control Protocol/Internet Protocol (TCP/IP).

18. An apparatus comprising:
a sensor node that includes one or more sensors configured to output power waveform data representative of measurements from an electrical power system; and
a gateway configured to execute, in a privileged space, a component that:
extracts at least one power-quality indicator of the electrical power system from the power waveform data; and
enforces, based at least in part on the power-quality indicator, a policy in connection with the electrical power system by performing at least one action in connection with the electrical power system, the sensor node, or the gateway.

19. The apparatus of claim 18, wherein the gateway is further configured to implement an operating system (OS) kernel that executes the component.

20. A method comprising:
outputting, by a sensor included in a computing system, power waveform data representative of measurements from an electrical power system; and
executing, by circuitry included in the computing system, a privileged-space component that:
extracts at least one power-quality indicator of the electrical power system from the power waveform data; and
enforces, based at least in part on the power-quality indicator, a policy in connection with the electrical power system by performing at least one action in connection with the electrical power system or the circuitry.

21. The system of claim 1, wherein:
the sensor is configured to continuously output the power waveform data as an uninterrupted data stream with no observation gaps; and
the circuitry is further configured to pre-process the uninterrupted data stream to produce at least two concurrent output representations comprising a cycle-aligned representation organized by electrical-cycle boundaries and a raw waveform representation preserving full sample-rate data.

22. The system of claim 21, wherein the circuitry is further configured to execute a plurality of concurrent analysis modalities, each analysis modality operating on at least one of the cycle-aligned representation or the raw waveform representation such that the plurality of concurrent analysis modalities operate simultaneously on the uninterrupted data stream without committing to any single analysis modality at capture time.

23. The system of claim 22, wherein the plurality of concurrent analysis modalities comprises at least two of:
per-cycle extraction that computes cycle-rate measurements from the cycle-aligned representation;
standards-aligned windowed analysis that computes standards-compliant measurements using standards-defined aggregation intervals;
frequency-domain processing that computes spectral representations from the raw waveform representation;
time-frequency processing that computes time-localized spectral representations using wavelet transforms;
sub-cycle transient detection that operates at full sample-rate resolution on the raw waveform representation;
demodulation that performs envelope extraction referenced to a phase reference;
power decomposition that separates apparent power into fundamental and non-fundamental contributions;
network model processing that performs topology-aware power-flow computation; or
compliance analysis that evaluates measured quantities against one or more power-quality standards.

24. The system of claim 22, wherein the circuitry is further configured to add one or more other analysis modalities to the plurality of concurrent analysis modalities without modifying any existing analysis modalities or recapturing the power waveform data.

25. The system of claim 22, wherein the plurality of concurrent analysis modalities collectively derive measurements across time scales that correspond to the uninterrupted data stream and span at least three orders of magnitude from the uninterrupted data stream, wherein the measurements comprise:
sub-cycle measurements at a time scale shorter than one electrical cycle; and
multi-cycle aggregated measurements at a time scale of at least one minute.

26. The system of claim 22, further comprising a runtime analytics engine configured to accept and execute user-defined or machine-generated analysis algorithms at runtime without modifying any of the concurrent analysis modalities or recompiling a core processing pipeline.

27. The system of claim 26, wherein the runtime analytics engine is deployable across multiple processing tiers that execute a common algorithmic definition, the multiple processing tiers comprising at least two of:
a sensor node;
an edge gateway;
a compute server; or
a cloud-based processing environment.

28. The system of claim 22, wherein the circuitry is further configured to implement a semantic enrichment layer that operates on structured features and signal representations produced by the plurality of concurrent analysis modalities, the semantic enrichment layer comprising at least one of:
a semantic engine that generates standards-grounded assertions from measured features;
a knowledge graph that maintains an event-driven topology with causal and temporal edges;
a waveform encoder that maps signal representations into vector embeddings for similarity-based retrieval; or
a retrieval-augmented generation (RAG) orchestration layer that provides tool-augmented reasoning over the structured features.

29. The system of claim 22, wherein the circuitry is further configured to:
derive the cycle-aligned representation and the raw waveform representation from the same power waveform data; and
make available the cycle-aligned representation and the raw waveform representation simultaneously to the plurality of concurrent analysis modalities such that each analysis modality selects which of the cycle-aligned representation and the raw waveform representation to consume based at least in part on one or more requirements of the concurrent analysis modalities.

30. The system of claim 21, wherein the circuitry is further configured to implement a phase-locked loop (PLL) that tracks an alternating-current fundamental of the power waveform data and provides a single timing reference that serves at least two of:
defining electrical-cycle boundaries for the cycle-aligned representation;
supplying a phase reference for deviation-based compression of the power waveform data; or
supplying a carrier reference for demodulation of the power waveform data.

31. The system of claim 30, wherein the PLL executes in a deterministic execution environment with guaranteed scheduling priority such that the single timing reference maintains coherence across a plurality of downstream functions served by the single timing reference.

32. The system of claim 21, wherein the circuitry is further configured to perform the pre-processing in a deterministic execution environment with a guaranteed scheduling priority that paces the uninterrupted data stream without data loss.

33. The system of claim 32, wherein the deterministic execution environment comprises at least one of:
an operating system kernel;
an extended Berkeley Packet Filter (eBPF) program;
microcontroller firmware; or
a field-programmable gate array (FPGA).
